(19) United States
(12) Patent Application Publication
(10) Pub. No.: US 2006/0227386 A1
(43) Pub. Date: Oct. 12, 2006

(54) Digital scanner calibration

(75) Inventors: Robert Eero Nuuja, Rochester, NY (US); Yingjun Bai, Webster, NY (US)

Correspondence Address: PATENT DOCUMENTATION CENTER, XEROX CORPORATION, 100 CLINTON AVE., SOUTH, XEROX SQUARE, 20TH FLOOR, ROCHESTER, NY, 14644, US

(73) Assignee: Xerox Corporation

(21) Appl. No.: 11/092,060

(22) Filed: Mar. 29, 2005

(51) Int. Cl. G03F 3/08

(52) U.S. Cl. 358/406; 358/1.9; 358/518

(57) ABSTRACT

Present systems and methods provide for accurate measurement of the colorant densities in a printed image using a calibrated digital scanner. The scanner is provided with a printed scanner calibration target with a plurality of color patches having known colorant density values. The scanner calibration target is scanned and the colorant density values that correspond to the scanned data are compared to the known values. Accordingly, the scanner profile can be adjusted to provide consistent and accurate measurement of the colorant densities in printed images.

### TECHNOLOGY

Present systems and methods relate to calibrating a digital scanner to obtain consistent and accurate measurement of the colorant densities in a printed image.

### BACKGROUND

Digital color printers typically receive and process color image signals that control the deposit of cyan, magenta, yellow, and black (CMYK) colorants in specified densities. Generally, all units of a color printer model use a single “color characterization profile” to map each CMYK input signal to an amount of colorant that will be deposited on the output sheet. While all units of the same model use the same color characterization, there are often noticeable differences in the colors that are output by different units in response to the same set of CMYK signals and also, in the colors that are output in response to the same input by a single printer over an extended period of time.

One reason for this “drift” in color is the variation in the electrostatic charge on toner particles that are inside the same cartridge. More specifically, later developed toner particles tend to be larger and/or have lower electrostatic charges. The use of larger and/or more toner particles causes a darkening of the colors that are printed later in the operating life of the toner cartridge. Changes in temperature, humidity and other environmental factors also contribute to color drift, as does the wear and tear of aging components. The drift is often magnified when one toner cartridge is replaced without replacing the others.

Color printers are typically calibrated to compensate for the drift in the colorant densities that are output by a printer. In a typical calibration process, a calibration target is printed in response to CMYK calibration signals that are received from an image processor linked to the printer being calibrated. The target is then scanned using an ordinary digital scanner to obtain a measurement of the density of each of the printed colorants. The measured values are then compared to a set of ideal values and the printer profile is adjusted based upon the comparison.

The drift associated with a scanner is typically much less than that associated with a printer. Accordingly, many printer calibration processes are based upon the erroneous assumption that the difference between the measured colorant density values and the known values result entirely from errors in the color characterization profile that is being used by the printer. In other words, it is assumed there are no inaccuracies in the scanner profile. However, scanners also experience color drift. For example, RGB values that are measured by scanners often vary due to aging of the lamp and/or imaging sensor and differences in lamp intensity among different scanners.

Thus, the aforementioned printer calibration processes often generate inconsistent results because they fail to account for the drift that is associated with the scanner when determining the color characterization for the printer.

### PRIOR ART

U.S. Patent Publication 20040114164 discloses a method of permitting an end user to recalibrate a color reproduction device. The color reproduction device includes a device for converting the native color values of the scanner into a device independent color space, a test target, and the desired values of each patch of the test target. The method includes printing the test target and scanning it with a scanner that forms a part of the color reproduction device. The device compares the desired values with the values obtained from scanning the printed test target to obtain a set of adjustment values to compensate for drift in the output of the color reproduction device. The compensation emphasizes restoration of the overall gray balance of the color reproduction device and can be implemented by modifying the tone reproduction curves or the halftone process used in the color reproduction device.

U.S. Pat. No. 6,048,117 discloses a network-based system for color calibration of a printer. A printing device is requested to generate a calibration test print. The printer generates a plurality of color patches and identification data which are put in hard copy form by a marker. The identification data includes data such as device identifiers, calibration print identifiers, and calibration statistics for the printing device. The hard copy calibration print is scanned and is transmitted to a calibration server. The calibration server interprets the coded data and determines the originating device, the calibration pattern printed, and an optimal color pattern based on the identification data. The color pattern printed is then compared to the optimal color pattern and their differences are determined. A color correction table is generated based on the differences and transmitted to the network address of the originating printer based on the identification data. The identification data provides for automatic recalibration of printing devices on a network.

U.S. Pat. Nos. 6,141,120 and 5,760,913 disclose a printer calibration methods and systems that use a personal computer equipped with a color laser server circuit card and a scanner to measure the color effects specific to a printer and to then calibrate print data to adjust for the measured printer effects. Each printer colorant is calibrated by printing a data file using the printer to be calibrated thereby generating a calibration image. The calibration image is next scanned using a scanner coupled to the printing system. The scanned data is compared to the data file which was sent to the printer to determine the relationship (an association) between the data file printed and the resulting calibration image. Color comparisons are made using an absolute density scale and thus the scanned data, being in RGB (Red, Blue, Green) format is converted to absolute density values. To determine the conversion from scanned RGB values to absolute density, a standard gray scale test strip is scanned and compared to a data file containing the known absolute density values which correspond to the test strip.

### SUMMARY

Aspects of the present systems and methods include a system that includes a scanner configured to generate a calibration target description that provides a digital representation of a printed scanner calibration target, the scanner being electronically connectable to a remotely located calibration server via a communications network; a network controller configured to transmit the calibration target description to the calibration server and to receive a scanner color correction file provided by the calibration server in response to receipt of the calibration target color description; and a scanner color correction file installer configured to store the received scanner color correction file in a memory accessible to the scanner.

In one aspect, a method includes generating a calibration target description that provides a digital representation of a printed scanner calibration target; and transmitting the calibration target description to a calibration server via a communications network; using the calibration target description to generate a scanner color correction file; receiving the scanner color correction file generated by the calibration server; and storing the scanner color correction file in a memory accessible to the scanner.

### BRIEF DESCRIPTION OF THE DRAWINGS

FIG. 1 provides an example of a network in which present systems and methods may be used;

FIG. 2 is an illustration showing the major components of a color MFD;

FIG. 3 is an example of a user interface that may be provided for use with present systems and methods;

FIG. 4 is an illustration showing scanner and printer calibration targets that may be used with present systems and methods;

FIG. 5 is a flow diagram showing exemplary steps that may be followed to calibrate a network color printer; and

FIG. 6 is a flow diagram illustrating the workflow used in the present systems and methods to recalibrate a network scanner.

### DETAILED DESCRIPTION

For a general understanding of the present systems and methods, reference is made to the drawings. In the drawings, like reference numerals have been used throughout to designate identical elements. In describing the present systems and methods, the following term(s) have been used in the description:

A “calibration target” is a set number of color patches that are used to measure the calorimetric response of an imaging device. The calibration targets used by printers, copiers and other output devices are typically provided by signals that are stored in the memory of the device. The calibration targets that are used by scanners and other image capture devices are usually provided as hardcopy patches that can be scanned or otherwise subjected to an image capture process.

A “calibration target description” is the set of digital values that define the color properties for a calibration target.

A “calibration server” is a software program that accepts measured color values, adjusts the measured values such that they conform to a set of ideal values and returns the adjusted values to the sending device.

A “calibration mode” refers to the type of device being calibrated.

A “color correction file” refers to the set of data that includes the adjusted color values.

A “dedicated network memory” refers to a storage location on a computer network that is reserved for storing a specified type of data, e.g., color descriptions. A “user memory” refers to a storage location that is accessible to and used by a specified user on the network. A user memory typically refers to a memory in a user operated PC.

A “network location identifier” refers to a number that identifies each device that sends and receives information over a network (e.g., as an IP Address).

A “model identifier” refers to a model number, product number or other identifier used to distinguish one device from another device.

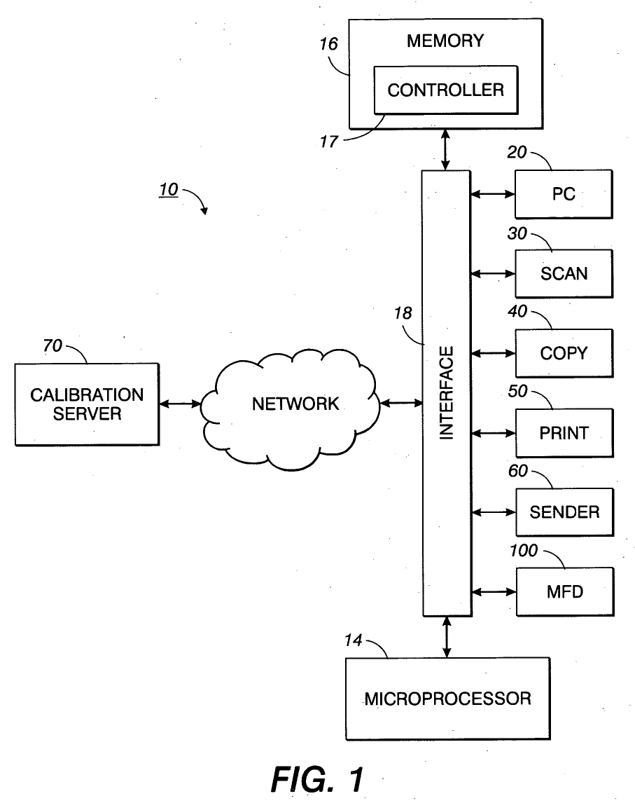

Referring to FIG. 1, present systems and methods may be used to calibrate a scanner 30 linked to a communications network 10. In one aspect, network 10 also includes a printer 50 and one or more other electronic devices, such as personal computers (PCs) 20, copiers 40, digital senders 60 and multi-functional devices (MFDs) 100. In the example shown, network 10 includes a calibration server 70. Notably, network 10 may be any network that is capable of facilitating communication between electronic devices such as, for example, a single PC 20, scanner 30 and calibration server 70 or it may include several devices that share common files or other resources.

In the example shown, PC 20, scanner 30, copier 40, printer 50, digital sender 60 and MFD 100 are independently connected to local network 12 via a network interface 18. Network 10 also includes a processor 14 and a memory 16, which may be provided with one or more electronic devices (e.g., PC 20, scanner 30, printer 50, MFD 100, etc.) or independently linked to local interface 18. Generally, memory 16 includes a network controller 17 that controls the communication of data between the various devices that are linked to network 10.

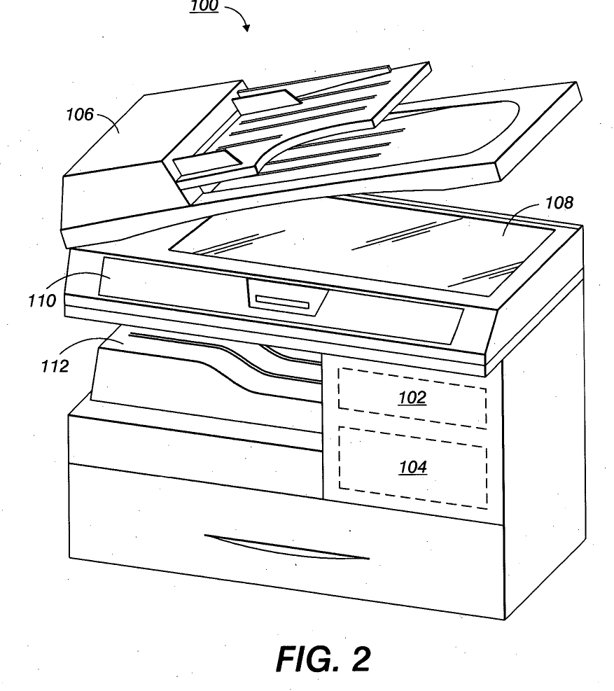

Referring to FIG. 2, a typical MFD 100 includes a digital scanner 102 that digitally captures images from hardcopy prints and a digital color printer 104 that generates hardcopy reproductions of digital image signals. MFD 100 also includes an image processor (IP) 120 that performs various functions, including converting the image data generated by scanner 102 from scanner color space (e.g., RGB) to printer color space (e.g., CMYK) MFD 100 may also include a document feeder 106, which can be used to transport original documents to a scanning platen 108 and it typically includes an output tray 110 for collecting hardcopy output. MFD 100 also includes a user interface (UI) 130 where users enter commands that operate MFD 100. While present systems and methods will be described herein with reference to MFD 100, it is understood that other digital imaging systems, such as those that scan and print original document using one or more stand alone scanners 30, printers 50 and/or other single function devices may also be used.

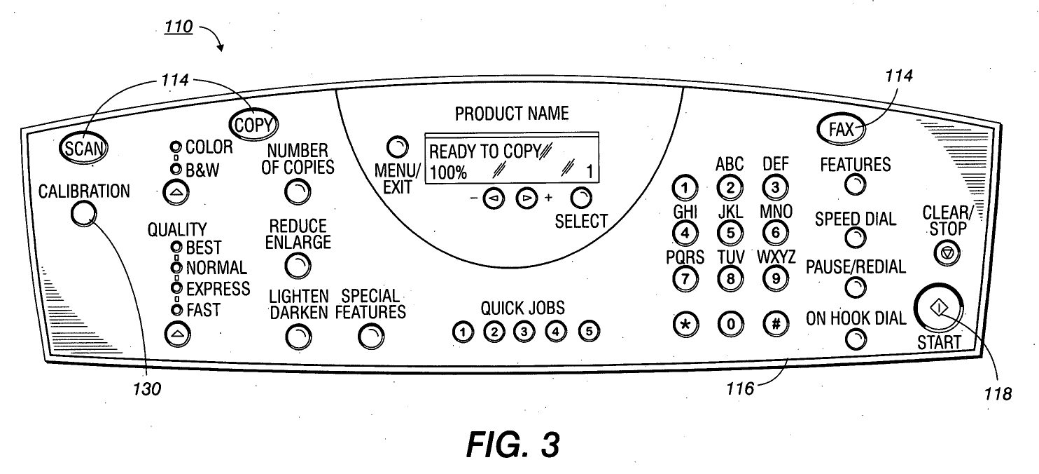

Turning to FIG. 3, UI 130 can be used to enter commands to operate MFD 100. For example, buttons 133-135 can be used to select among the “scan,” “copy” and “fax” modes of operation for MFD 100. For example, user can select scan button 133 to obtain digital representations of hardcopy documents that have been positioned on scanning platen 108 and copy button 134 may be selected to generate printed reproductions of hardcopy original documents using the combined functionality of scanner 102 and printer 104. MFD 102 may also be connected to a telecommunications channel (e.g., a telephone line, a broadband connection, etc.), in which case UI 130 will typically have a telecommunications key pad 136 with a fax button 135 that the user can select to transmit images that are captured by scanner 102 to remote facsimile machines. The available functions are typically initiated using a start button 132. In the illustrated example, UI 130 also has a calibration button 138 that may be selected to calibrate scanner 102 and color printer 104 to maintain consistent and accurate color reproduction.

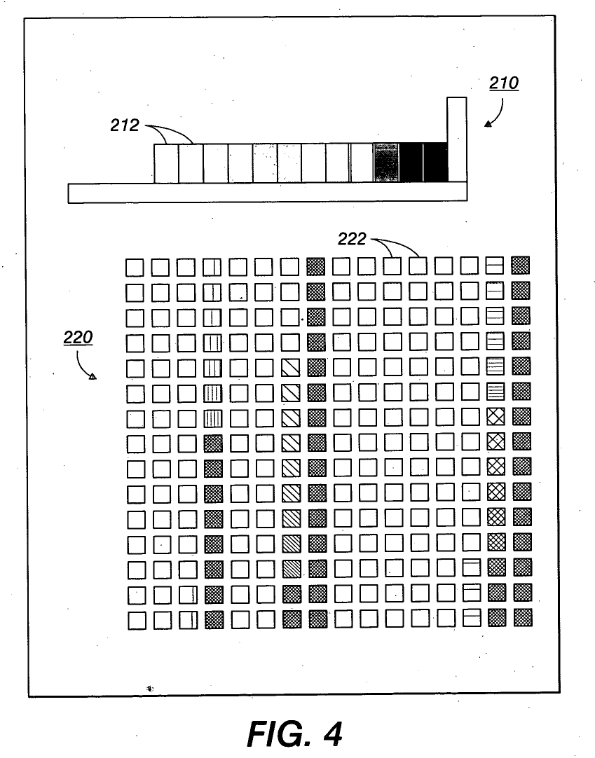

Turning to FIG. 4, present systems and methods will typically be used in to calibrate a scanner 102 and/or printer 104 that is connected to network 10. In one aspect, scanner 102 is provided with a hardcopy scanner calibration target 210 that has a plurality of patches 212, each having a known color value. Printer 104 receives CMYK signals from IP 120 that correspond to a set of stored ideal RGB values and generates color output by mapping them to the printer characterization profile. In one aspect, IP 120 provides CMYK calibration signals, which are used by printer 104 to generate a printer calibration target 220 with a plurality of color patches 222.

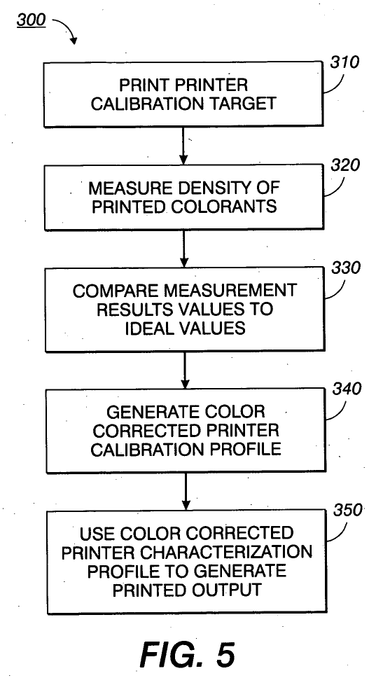

Turning to FIG. 5, in a printer calibration process 300, a user may enter commands at UI 130 to request printing of the printer calibration target 220 as shown in block 310. The user then positions the printed printer calibration target on scanning platen 108 and again through UI 130, requests scanning of the printer calibration target as shown in block 320. The data generated during the scan is temporarily stored in IP 120, where it is analyzed to determine the density of the C, M, Y and K colorants. The measured density values are then compared to the device independent values that correspond to the values that are pre-stored in IP 120 as shown in block 330. The comparison of the measured and ideal values is then used to derive a color corrected printer calibration profile 204 that compensates for drift as shown at block 340. Printer 104 then generates hardcopy prints using the color corrected printer calibration profile 204 as shown in block 350.

Present systems and methods use scanner 102 to measure the densities of colorants that are output by printer 104. More specifically, colorant density measurement (block 330) is performed by scanning the printer calibration target 220 and comparing the results of the scan to the known values that correspond to the RGB calibration signals that are pre-stored in IP 120. In one aspect, the RGB data generated by scanner 102 is mapped to a set of device independent values using the color characterization profile for scanner 102. Like the printer characterization profile, a scanner characterization profile is usually a generic color profile for a selected scanner model. Since the RGB values that are generated by different units of the same scanner model often vary, the use of a generic scanner profile often leads to inaccurate calibration results.

Present systems and methods can be used to continuously calibrate a scanner 102 and thus, avoid the use of a generic scanner profile. In one aspect, present systems and methods can be used to calibrate a scanner 102 and a printer 104 that are electronically linked to calibration server 70 via communications network 10. Accordingly, any drift that would otherwise be introduced by scanner 102 is eliminated before scanner 102 is used to measure the colorant densities for printer calibration target 220.

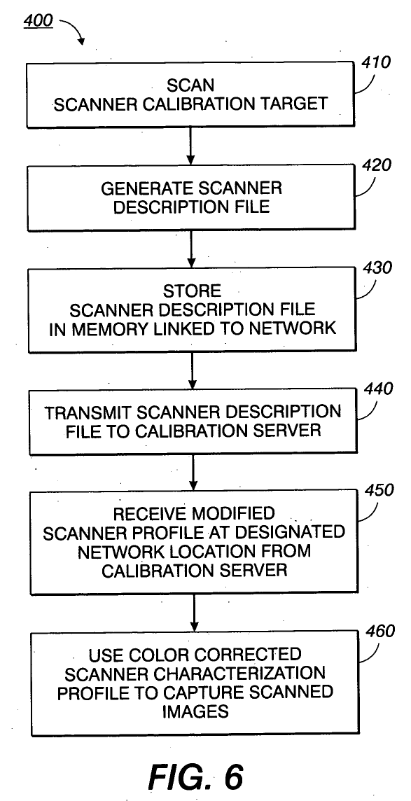

Referring to FIG. 6, a user may initiate scanner calibration method 400 by selecting a calibration button 138 at UI 130 to enter a calibration mode and then selecting a scan button 133 to direct calibration of scanner 102. As indicated in block 410, scanner calibration method 400 includes scanning a scanner calibration target 210 that has been positioned on scanner 102. In one aspect, scanner calibration method 400 may be performed using a scanner calibration target 210 that is scanned simultaneously with a printer calibration target 220. In another aspect, scanner calibration may be performed using a scanner calibration target 210 that is scanned independently.

A scanner calibration target description that includes RGB values that are obtained by scanning scanner calibration target 210 is then generated as shown in block 420. In one aspect, the scanner calibration target description generally includes RGB data generated during the scan and an IP address or other network location identifier for MFD 100. The scanner calibration target description may also include the model number or other identifying information for MFD 100 and/or an indication of the calibration mode being operated, i.e., whether the device being calibrated is a scanner, printer, copier, etc.

As set forth above, network controller 17 controls the communication of data between the various devices that are linked to network 10. As shown in block 430, network controller 17 obtains the scanner calibration target description from network interface 18 and transmits it to calibration server 70 for color correction. In one aspect, the scanner calibration target description is stored in a memory 16 that is linked directly to network 10 and designated for storing scanner calibration target color descriptions. In another aspect, the scanner calibration target description may be stored in a memory that is linked to a user operated PC 20. In either case, the scanner calibration target description is retrieved from memory and transmitted to calibration server 70 as shown in block 440. In one aspect, the scanner calibration target description includes all of the RGB data that is generated by when scanner calibration target 210 is scanned. It is understood, however, that the scanner calibration target description may include the average RGB value for each patch rather than the full set of RGB data in order to avoid the transfer of large files electronic transmission.

In one aspect, the scanner calibration target description may be transmitted from network 10 to calibration server 70 as an attachment to an electronic mail note using an e-mail address that is associated with the memory that is designated for storing scanner calibration target color descriptions. For example, when the scanner calibration target description is stored in a location of network 10 that has been designated for storing scanner calibration target color descriptions, it may be transmitted to calibration server 70 using a designated network 10 e-mail address. When the scanner calibration target description is stored in a location that can be accessed by a specified user it may be transmitted to calibration server 70 from the user's e-mail address.

Calibration server 70 compares the data that represents the measured RGB values to the known color value for each patch 212 to generate a scanner color correction file. The scanner color correction file is then returned to the sending location in network 10 as shown in block 450 as a replacement for the existing scanner characterization profile as shown in block 460. In one aspect, calibration server 70 may generate a service call signal when the difference in the measured and known color values indicates that scanner 102 is out of specification.

While present systems and methods have been described as using scanner calibration target color descriptions that are transmitted from network 10 to calibration server 70 via e-mail, it is understood that several other alternatives are available. For example, the scanner calibration target description could be uploaded to calibration server 70 from a network 10 scanner calibration target description storage location, from a memory linked to a PC 22 or 23 or from another suitable storage media. Similarly, it is understood that present systems and methods may provide a link that can be used by network 10 to download the file, rather than deliver the scanner color correction file by e-mail. In one aspect, present systems and methods may provide a calibration server 70 that is configured to deliver software that can be used to perform the color correction on the RGB data that is generated by scanner 102, rather than perform the color correction. In another aspect, calibration server 70 may be configured to provide a link that can be used by network 10 to download the color correction software.

Present systems and methods can be used to maintain consistent color reproduction characteristics in a scanner. Accordingly, the print calibration process will provide much better color consistency across different devices and the overall color quality of the product will be much more consistent and predictable. The proposed workflow takes advantage of the network scanning capability of the MFD and works for both scanner characterization and calibration.

It will be appreciated that various of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A system, comprising:
a scanner configured to generate a calibration target description that provides a digital representation of a printed scanner calibration target, said scanner being electronically connectable to a remotely located calibration server via a communications network;
a network controller configured to transmit said calibration target description to said calibration server and to receive a scanner color correction file provided by said calibration server in response to receipt of said calibration target color description; and
a scanner color correction file installer configured to store said received scanner color correction file in a memory accessible to said scanner.

2. A system as claimed in claim 1 wherein said scanner is further configured to provide said calibration target description as a file stored in a memory and said network controller is further configured to retrieve said calibration target description file from said memory and transmit said calibration target description file to said calibration server as an electronic mail note.

3. A system as claimed in claim 2 wherein said scanner is further configured to provide said calibration target description as a file stored in a network memory dedicated to storing calibration target description files and said network controller is further configured to retrieve said calibration target description file from said dedicated network memory and transmit said calibration target description file to said calibration server as an electronic mail note using a dedicated network e-mail address.

4. A system as claimed in claim 2 wherein said scanner is further configured to provide said calibration target description as a file stored in a user memory and said network controller is further configured to retrieve said calibration target description file from said user memory and transmit said calibration target description file to said calibration server as an electronic mail note using a user e-mail address.

5. A system as claimed in claim 2 wherein said calibration target description includes a network location identifier for said scanner.

6. A system as claimed in claim 2 wherein said calibration target description includes a model identifier for said scanner.

7. A system as claimed in claim 2 wherein said calibration target description identifies a calibration mode for said network location identifier for said scanner.

8. A system as claimed in claim 2 wherein said network controller is further configured to receive said scanner color correction file as an attachment to an electronic mail note and said scanner color correction file installer is further configured to save said electronic mail note in said scanner accessible memory.

9. A system as claimed in claim 1 wherein said scanner is further configured to generate a calibration target description that provides a digital representation of a printed image generated by mapping printer calibration target signals received from an image processor to a color characterization profile for a printer electronically linked to said scanner via said communications network.

10. A system as claimed in claim 1 wherein said calibration target description provides an average color value for each color printed on said calibration target.

11. A method, comprising:
generating a calibration target description that provides a digital representation of a printed scanner calibration target;
transmitting said calibration target description to a calibration server via a communications network;
using said calibration target description to generate a scanner color correction file;
receiving said scanner color correction file generated by said calibration server; and
storing said scanner color correction file in a memory accessible to said scanner.

12. A method as claimed in claim 11 further comprising transmitting said calibration target description file to said calibration server as an electronic mail note.

13. A method as claimed in claim 12 further comprising:
retrieving said calibration target description file from a memory linked directly to said network; and
transmitting said calibration target description file to said calibration server as an electronic mail note using a network e-mail address.

14. A method as claimed in claim 12 further comprising:
retrieving said calibration target description file from a memory linked to a user PC; and
transmitting said calibration target description file to said calibration server as an electronic mail note using a user e-mail address.

15. A method as claimed in claim 12 wherein said calibration target description includes a network location identifier for said scanner.

16. A method as claimed in claim 12 wherein said calibration target description includes a model identifier for said scanner.

17. A method as claimed in claim 12 wherein said calibration target description identifies a calibration mode for said network location identifier for said scanner.

18. A method as claimed in claim 12 further comprising:
receiving said scanner color correction file as an attachment to an electronic mail note; and
saving said color correction file electronic mail note in said scanner accessible memory.

19. A method as claimed in claim 11 further comprising:
generating a calibration target description that provides a digital representation of a color printed image; and
calibrating a color printer used to generate said printed image.

20. A method as claimed in claim 11 wherein said calibration target description provides an average color value for each color printed on said calibration target.
